(19) United States
(12) Patent Application Publication
(10) Pub. No.: US 2022/0069063 A1
(43) Pub. Date: Mar. 3, 2022

(54) DISPLAY DEVICE

(71) Applicant: Samsung Display Co., Ltd., Yongin-Si (KR)

(72) Inventors: DONGWOO KIM, Seoul (KR); MUN-SOO PARK, Suwon-si (KR); JONGHWAN PARK, Hwaseong-si (KR)

(21) Appl. No.: 17/313,361

(22) Filed: May 6, 2021

(30) Foreign Application Priority Data
Aug. 26, 2020 (KR) 10-2020-0108127

(51) Int. Cl. H01L 27/32; H01L 51/52

(52) U.S. Cl. CPC H01L 27/3293; H01L 51/5284; H01L 27/322

(57) ABSTRACT

A display device includes a plurality of display panels. Each of the display panels includes a substrate and a light blocking member. The substrate includes a display area and a peripheral area, and the display area includes sub-pixel areas. The light blocking member is disposed in the display area and the peripheral area on the substrate, and a plurality of openings is defined through the light blocking member to overlap the sub-pixel areas. A first width of the light blocking member located between two adjacent openings among the openings is twice a width of the light blocking member located in the peripheral area.

This application claims priority to Korean Patent Application No. 10-2020-0108127, filed on Aug. 26, 2020, and all the benefits accruing therefrom under 35 U.S.C. § 119, the content of which in its entirety is herein incorporated by reference.

### BACKGROUND

### 1. Field

Embodiments relate generally to a display device. More particularly, embodiments of the invention relate to a display device including a display panel.

### 2. Description of the Related Art

Flat panel display devices are widely used as display devices for replacing a cathode ray tube display device due to lightweight and thin characteristics thereof. Such flat panel display devices may include a liquid crystal display device and an organic light emitting diode display device.

Recently, a display device (e.g., a tiling display device) in which at least two display panels are combined to implement a large display panel has been developed. In such a display device, the display panels may be a same display panel, and each of the display panels may include a display area and a peripheral area surrounding the display area. In such a display device, the display area refers to an area in which an image is displayed, and a pixel and the like may be disposed in the display area. In addition, the peripheral area refers to an area in which an image is not displayed, and signal wires and the like may be disposed in the peripheral area. Moreover, the display panels may be arranged in a lattice shape.

### SUMMARY

In a display device (e.g., a tiling display device) in which at least two display panels are combined, a plurality of stripes at a boundary where the display panels are adjacent to each other may be visually recognized in an image displayed thereon by a user due to a peripheral area of the display panels in which the image is not displayed such that display quality of the display device may be impaired.

Some embodiments provide a display device including a plurality of display panels.

According to an embodiment, a display device includes a plurality of display panels. Each of the display panels includes a substrate and a light blocking member. In such an embodiment, the substrate includes a display area and a peripheral area, and the display area includes sub-pixel areas. In such an embodiment, the light blocking member is disposed in the display area and the peripheral area on the substrate, and a plurality of openings is defined through the light blocking member to overlap the sub-pixel areas. In such an embodiment, a first width of the light blocking member located between two adjacent openings among the openings is twice a width of the light blocking member located in the peripheral area.

In an embodiment, the openings may have a same size and a same shape as each other.

In an embodiment, in a plan view of the display device, the display panels may be repeatedly arranged in a first direction and a second direction orthogonal to the first direction.

In an embodiment, the display panels may be arranged in a lattice shape.

In an embodiment, a second width of the light blocking members disposed in two adjacent peripheral areas among the peripheral areas in adjacent display panels among the display panels may be equal to the first width.

In an embodiment, a width of the light blocking member located between two openings which are adjacent to each other in a first direction among the openings may be equal to a width of the light blocking member located between two openings which are adjacent to each other in a second direction orthogonal to the first direction among the openings.

In an embodiment, the display panels may have a same size and a same shape as each other.

In an embodiment, the display panels may include a first display panel and a second display panel making contact with a first side of the first display panel, and the first display panel and the second display panel may be arranged in a first direction.

In an embodiment, a total width of a peripheral area of the first display panel and a peripheral area of the second display panel in the first direction, which are adjacent to a boundary where the first display panel and the second display panel make contact with each other, may be equal to a width of the light blocking member located between two openings which are adjacent to each other in the first direction among the openings.

In an embodiment, the display panels may further include a third display panel making contact with a second side of the first display panel, and the first display panel and the third display panel may be arranged in a second direction orthogonal to the first direction.

In an embodiment, a total width of a peripheral area of the first display panel and a peripheral area of the third display panel in the second direction, which are adjacent to a boundary where the first display panel and the third display panel make contact with each other, may be equal to a width of the light blocking member located between two openings which are adjacent to each other in the second direction among the openings.

In an embodiment, the total width of the peripheral area of the first display panel and the peripheral area of the second display panel in the first direction, which are adjacent to the boundary where the first display panel and the second display panel make contact with each other, may be equal to the total width of the peripheral area of the first display panel and the peripheral area of the third display panel in the second direction, which are adjacent to the boundary where the first display panel and the third display panel make contact with each other.

In an embodiment, the sub-pixel areas may include first, second, and third sub-pixel areas, and each of the display panels may further include first, second, and third sub-pixel structures disposed in the first to third sub-pixel areas on the substrate, respectively.

In an embodiment, each of the display panels may further include first, second, and third optical filters disposed on the first to third sub-pixel structures, respectively and first, second, and third color filters disposed on the first to third optical filters, respectively.

In an embodiment, the first to third color filters may be disposed in the openings, respectively.

In an embodiment, opposing side portions of the light blocking member in the display area may be disposed between the first optical filter and the first color filter, between the second optical filter and the second color filter, and between the third optical filter and the third color filter.

In an embodiment, sub-pixel areas located at an outermost periphery of among the sub-pixel areas in one of the display panels may be aligned with a boundary between the display area and the peripheral area.

In an embodiment, in a plan view of the display device, the sub-pixel areas may be repeatedly arranged in a first direction and a second direction orthogonal to the first direction.

In an embodiment, the peripheral area may surround the display area, and the light blocking member may be disposed in the peripheral area and the display area except for the sub-pixel areas.

In embodiments of the display device according to the invention, the first and second widths and of the light blocking member disposed in the display area may be the same as the third and fourth widths and of the light blocking member disposed in the two adjacent peripheral areas. Accordingly, when a user of the display device views an image displayed on the display device, the user may not visually perceive a line at a boundary between adjacent display panels in the image.

In such embodiments, when a large display panel is implemented by using the first, second, third, and fourth display panels, which are small display panels having relatively low prices, a total manufacturing cost of the display device including the large display panel may be relatively reduced.

### BRIEF DESCRIPTION OF THE DRAWINGS

The above and other features of the invention will become more apparent by describing in further detail embodiments thereof with reference to the accompanying drawings, in which:

FIG. 1 is a plan view showing a display device according to an embodiment of the invention;

FIG. 2 is a plan view for describing display panels included in the display device of FIG. 1;

FIG. 3 is a plan view for describing a display area, a peripheral area, and sub-pixel areas included in a display area of FIG. 2;

FIG. 4 is a cross-sectional view taken along line I-I′ of the display device of FIG. 2;

FIG. 5 is a cross-sectional view taken along line II-II′ of the display device of FIG. 2;

FIG. 6 is a cross-sectional view taken along line III-III′ of the display device of FIG. 2;

FIG. 7 is a cross-sectional view taken along line IV-IV′ of the display device of FIG. 2;

FIG. 8 is a plan view showing a display device according to an alternative embodiment of the invention;

FIG. 9 is a plan view showing a display device according to an embodiment of the invention; and

FIG. 10 is a plan view showing a display device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of a display device according to the invention will be described in detail with reference to the accompanying drawings.

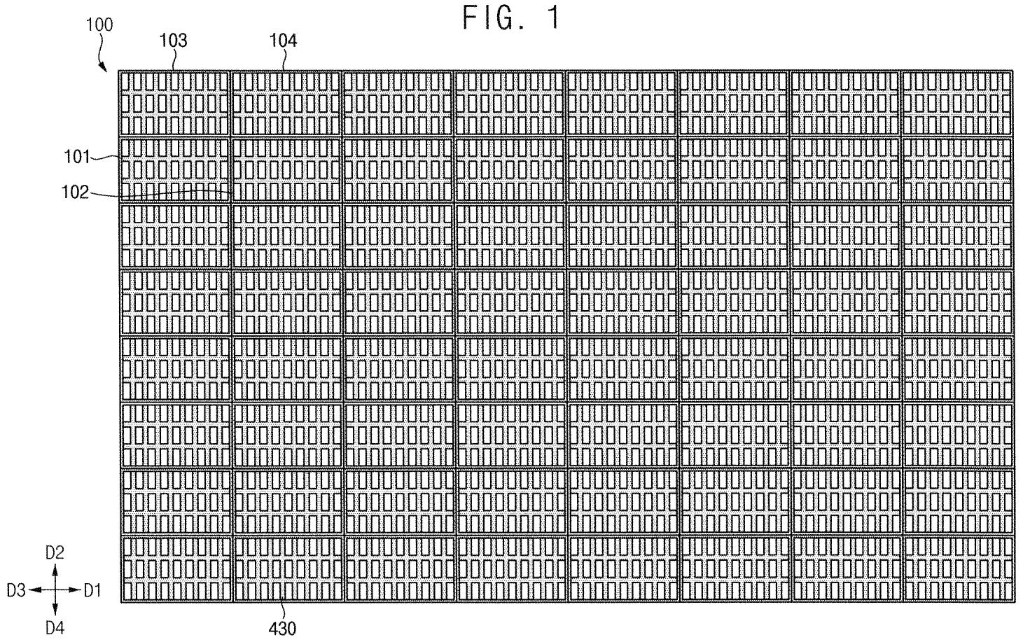

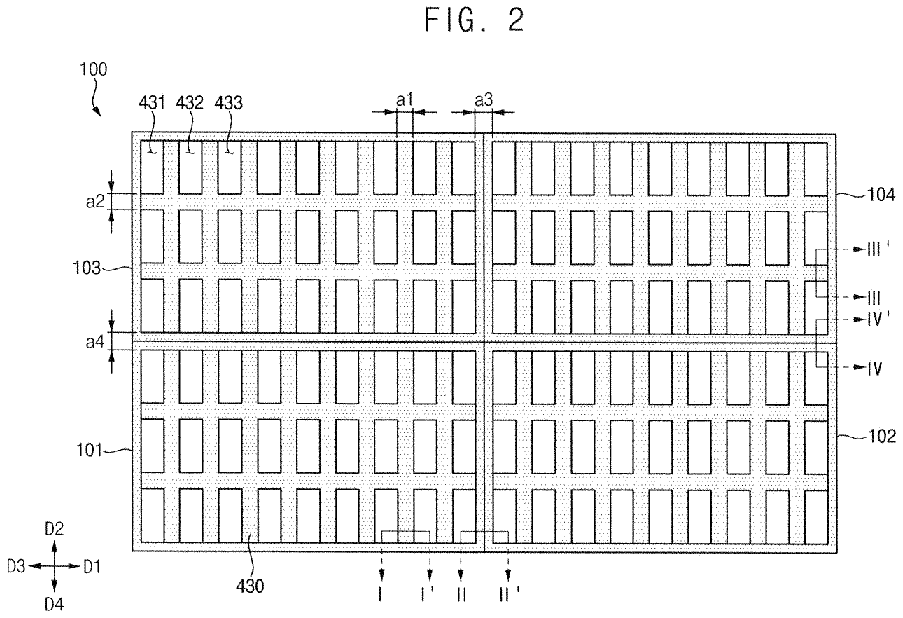

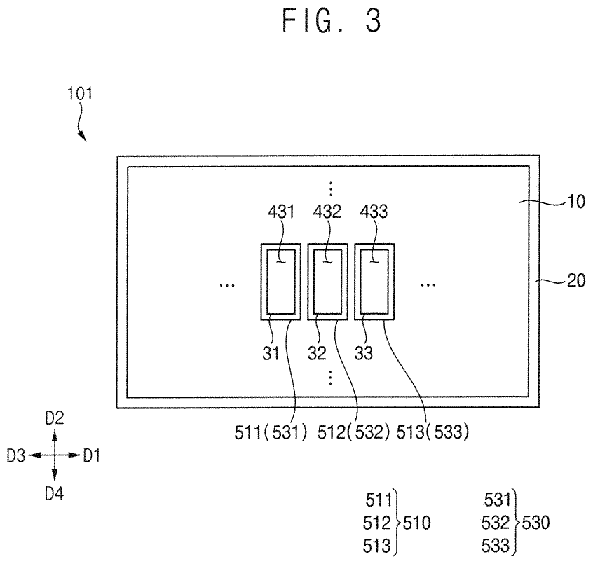

FIG. 1 is a plan view showing a display device according to an embodiment of the invention, and FIG. 2 is a plan view for describing display panels included in the display device of FIG. 1. FIG. 3 is a plan view for describing a display area, a peripheral area, and sub-pixel areas included in a display area of FIG. 2.

Referring to FIGS. 1, 2, and 3, an embodiment of a display device 100 may include first, second, third, and fourth display panels 101, 102, 103, and 104. In an embodiment, the first, second, third, and fourth display panels 101, 102, 103, and 104 may have a same size and a same shape as each other. In a plan view of the display device 100, the first, second, third, and fourth display panels 101, 102, 103, and 104 may be repeatedly arranged in a first direction D1 and a second direction D2 that is substantially orthogonal to the first direction D1. In such an embodiment, the first, second, third, and fourth display panels 101, 102, 103, and 104 may be arranged in a lattice shape. In one embodiment, for example, as shown in FIG. 2, a first side of the first display panel 101 may make contact with the second display panel 102, and the first and second display panels 101 and 102 may be arranged in the first direction D1. In such an embodiment, a second side of the first display panel 101 may make contact with the third display panel 103, and the first and third display panels 101 and 103 may be arranged in the second direction D2. In such an embodiment, a first side of the third display panel 103 and a first side of the second display panel 102 may make contact with the fourth display panel 104, and the third and fourth display panels 103 and 104 may be arranged in the first direction D1. In such an embodiment, the second and fourth display panels 102 and 104 may be arranged in the second direction D2. In an embodiment, as described above, the first, second, third, and fourth display panels 101, 102, 103, and 104 may be repeatedly arranged to implement the display device 100 shown in FIG. 1.

Referring to FIGS. 2 and 3, in an embodiment, each of the first, second, third, and fourth display panels 101, 102, 103, and 104 may have a display area 10 and a peripheral area 20. In such an embodiment, the peripheral area 20 may substantially surround the display area 10. The display area 10 may include first, second, and third sub-pixel areas 31, 32, and 33. The first, second, and third sub-pixel areas 31, 32, and 33 may be arranged in the first direction D1, and may be spaced apart from each other. In such an embodiment, the second sub-pixel area 32 may be spaced apart from the first sub-pixel area 31 in the first direction D1, and the third sub-pixel area 33 may be spaced apart from the second sub-pixel area 32 in the first direction D1. In one embodiment, for example, in a plan view of the display device 100, the first, second, and third sub-pixel areas 31, 32, and 33 may be repeatedly arranged in the first direction D1 and the second direction D2.

In an embodiment, as shown in FIG. 2, sub-pixel areas located at an outermost periphery of each of the first, second, third, and fourth display panels 101, 102, 103, and 104 among the first, second, and third sub-pixel areas 31, 32, and 33 may be aligned with a boundary between the display area 10 and the peripheral area 20. In such an embodiment, at least one side of each of the sub-pixel areas located at the outermost periphery among the first, second, and third sub-pixel areas 31, 32, and 33 may overlap the boundary. In one embodiment, for example, each of sub-pixel areas adjacent to a corner of the display area 10 among the sub-pixel areas located at the outermost periphery may have two sides aligned with the boundary, and each of sub-pixel areas that are not adjacent to the corner of the display area 10 among the sub-pixel areas located at the outermost periphery may have one side aligned with the boundary.

In such an embodiment, the display areas 10 included in each of the first, second, third, and fourth display panels 101, 102, 103, and 104 may have a same size and a same shape as each other, the peripheral areas 20 included in each of the first, second, third, and fourth display panels 101, 102, 103, and 104 may have a same size and a same shape as each other, and the first, second, and third sub-pixel areas 31, 32, and 33 included in each of the first, second, third, and fourth display panels 101, 102, 103, and 104 may have a same size and a same shape as each other.

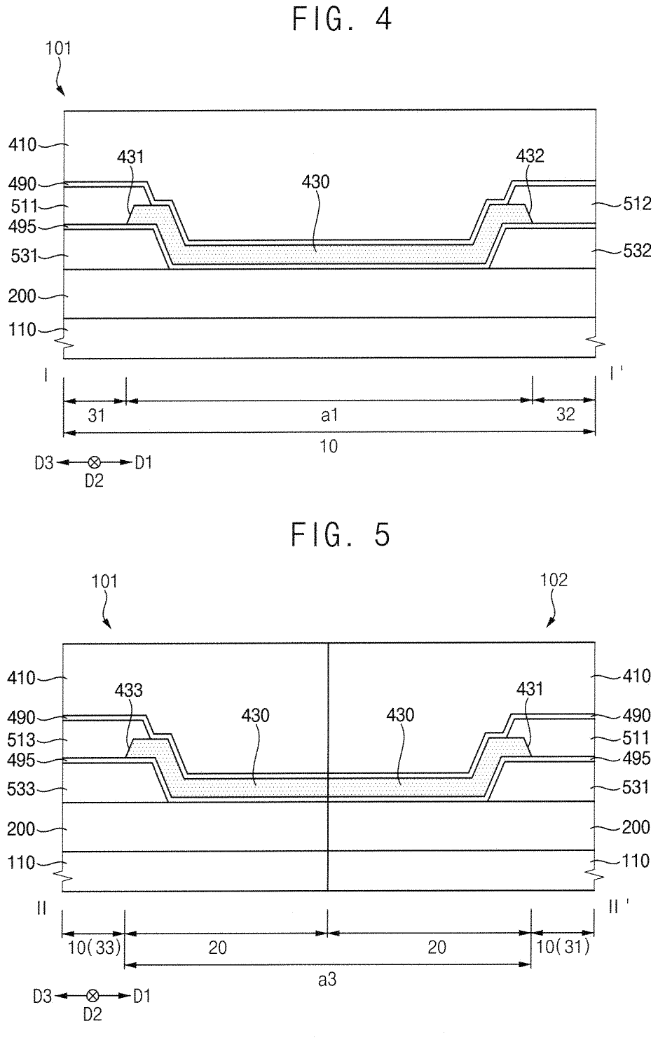

In an embodiment, each of the first, second, third, and fourth display panels 101, 102, 103, and 104 may include first to third sub-pixels (e.g., sub-pixels included in a sub-pixel structure 200 of FIGS. 4 to 7). In such an embodiment, the sub-pixels included in each of the first to fourth display panels 101, 102, 103, and 104 may have a same structure as each other. The first to third sub-pixels may be disposed in the first to third sub-pixel areas 31, 32, and 33, respectively. In such an embodiment, shapes of the first to third sub-pixel areas 31, 32, and 33 and shapes of the first to third sub-pixels may be the same as each other. In one embodiment, for example, the first sub-pixel disposed in the first sub-pixel area 31 may emit red light, the second sub-pixel disposed in the second sub-pixel area 32 may emit green light, and the third sub-pixel disposed in the third sub-pixel area 33 may emit blue light. The display device 100 may display an image through the first to third sub-pixels. In an alternative embodiment, a sub-pixel configured to emit green or blue light may be disposed in the first sub-pixel area 31, a sub-pixel configured to emit red or blue light may be disposed in the second sub-pixel area 32, and a sub-pixel configured to emit red or green light may be disposed in the third sub-pixel area 33.

In an embodiment, the first to fourth display panels 101, 102, 103, and 104 may further include signal wires disposed in the peripheral area 20. In such an embodiment, the signal wire may extend from the peripheral area 20 to the display area 10 to be electrically connected to the sub-pixel structures. In one embodiment, for example, signals and power supply voltages may be provided from an external device configured to generate signals and power supply voltages to the signal wire disposed in the peripheral area 20, and the signals and the power supply voltages may be provided to the sub-pixel structures through the signal wire.

Referring to FIGS. 2 and 3, each of the first, second, third, and fourth display panels 101, 102, 103, and 104 may further include a light blocking member 430.

In each of the first, second, third, and fourth display panels 101, 102, 103, and 104, the light blocking member 430 may be disposed in the display area 10 and the peripheral area 20, and first, second, and third openings 431, 432, and 433 that overlap the first, second, and third sub-pixel areas 31, 32, and 33, respectively, may be defined through the light blocking member 430. In such an embodiment, the light blocking member 430 may be disposed in the display area 10 except for the first, second, and third sub-pixel areas 31, 32, and 33, and the peripheral area 20. In one embodiment, for example, the first opening 431 may overlap the first sub-pixel area 31, the second opening 432 may overlap the second sub-pixel area 32, and the third opening 433 may overlap the third sub-pixel area 33. Light generated from the sub-pixels may be emitted to an outside through the first to third openings 431, 432, and 433.

In an embodiment, since the light blocking member 430 is disposed in the display area 10, semiconductor elements, signal wires, and the like disposed in the display area 10 and included in the sub-pixel structure may be blocked from being reflected by external light, and since the light blocking member 430 is disposed in the peripheral area 20, signal wires disposed in the peripheral area 20 may be blocked from being reflected by the external light.

In such an embodiment, since the first, second, and third sub-pixel areas 31, 32, and 33 have a same size and a same shape as each other, the first to third openings 431, 432, and 433 may have a same size and a same shape as each other.

In an embodiment, a first width a1 and a second width a2 of the light blocking member 430 located between two adjacent openings among the first to third openings 431, 432, and 433 may be equal to each other. In one embodiment, for example, the first width a1 may correspond to a width of the light blocking member 430 located between two openings that are adjacent to each other in the first direction D1 among the first to third openings 431, 432, and 433, and the second width a2 may correspond to a width of the light blocking member 430 located between two openings that are adjacent to each other in the second direction D2 among the first to third openings 431, 432, and 433.

In an embodiment, a third width a3 and a fourth width a4 of the light blocking members 430 disposed in two adjacent peripheral areas among the peripheral areas 20 in adjacent display panels among the first, second, third, and fourth display panels 101, 102, 103, and 104 may be the same as the first width a1 and the second width a2. In such an embodiment, the third width a3 of the peripheral area 20 of the first display panel 101 and the peripheral area 20 of the second display panel 102 in the first direction D1, which are adjacent to a boundary where the first display panel 101 and the second display panel 102 make contact with each other, may be equal to the first width a1 of the light blocking member 430 located between the two openings that are adjacent to each other in the first direction D1 among the first to third openings 431, 432, and 433. In such an embodiment, the fourth width a4 of the peripheral area 20 of the first display panel 101 and the peripheral area 20 of the third display panel 103 in the second direction D2, which are adjacent to a boundary where the first display panel 101 and the third display panel 103 make contact with each other, may be equal to the second width a2 of the light blocking member 430 located between the two openings that are adjacent to each other in the second direction D2 among the first to third openings 431, 432, and 433. In such an embodiment, the third width a3 of the peripheral area 20 of the first display panel 101 and the peripheral area 20 of the second display panel 102 in the first direction D1, which are adjacent to the boundary where the first display panel 101 and the second display panel 102 make contact with each other, may be equal to the fourth width a4 of the peripheral area 20 of the first display panel 101 and the peripheral area 20 of the third display panel 103 in the second direction D2, which are adjacent to the boundary where the first display panel 101 and the third display panel 103 make contact with each other. Accordingly, the first width a1, the second width a2, the third width a3, and the fourth width a4 may all be equal to each other.

In an embodiment, each of the first to fourth widths a1, a2, a3, and a4 may be twice a width of the light blocking member 430 located in the peripheral area 20 of each of the first, second, third, and fourth display panels 101, 102, 103, and 104.

Accordingly, the display device 100 including the first, second, third, and fourth display panels 101, 102, 103, and 104 may be provided.

In a conventional display device in which at least two display panels are combined to implement a large display panel, the display panels may be a same display panel as each other, and each of the display panels may include a display area 10 and a peripheral area 20. The display panels may be arranged in a lattice shape. In such a conventional display device, in a portion where the display panels are adjacent to each other, a plurality of stripes may be visually recognized by a user due to the peripheral area 20 in which the image is not displayed. Accordingly, when the user views an image displayed by such a conventional display device, the user may visually perceive unnaturalness. In such a conventional display device, since a width of a light blocking member located in the display area 10 and a width of the light blocking member located in the peripheral area 20 are different from each other, the light blocking member located in the peripheral area 20 may be recognized by the user. In such a conventional display device, the width of the light blocking member located in the peripheral area 20 may be greater than the width of the light blocking member located in the display area 10. In a display device having an 8K resolution (e.g., including 7680×4320 pixels) and having a lateral length of 16 meters and a longitudinal length of 9 meters, 100 display panels (e.g., 10×10 display panels), each having a lateral length of 1.6 meters and a longitudinal length of 0.9 meters, may be combined to implement a large display panel. In such a display device, the display panel having the lateral length of 1.6 meters and the longitudinal length of 0.9 meters may have a peripheral area 20 having a relatively large width.

In an embodiment of the invention, when a lateral length of the display device 100 is 16 meters, and a longitudinal length of the display device 100 is 9 meters, each of the first, second, third, and fourth display panels 101, 102, 103, and 104 may be used to implement a large display panel by combining 10000 display panels (e.g., 100×100 display panels) having a lateral length of 16 centimeters and a longitudinal length of 9 centimeters. In such an embodiment, the display panel having the lateral length of 16 centimeters and the longitudinal length of 9 centimeters may have a peripheral area 20 having a relatively small width (e.g., 7 mm or less). In one embodiment, for example, the display device 100 may be used as a display device for an exhibition or a display device for an electronic display board. In such an embodiment, a distance between the display device 100 and the user viewing the display device 100 may be several meters or more, so that the light blocking member 430 disposed in the peripheral area 20 of the display panel may not be visually recognized. In such an embodiment, a size of the sub-pixel may be increased (e.g., a size of each of the first, second, and third sub-pixel areas 31, 32, and 33 may be increased), so that the width of the light blocking member 430 disposed in the display area 10 may be equal to the width of the light blocking members 430 disposed in two peripheral areas 20 located in adjacent display panels. In such an embodiment, the width of the light blocking member 430 disposed in the display area 10 may be increased to correspond to the increased size of the sub-pixel, so that the width of the light blocking member 430 disposed in the display area 10 may be equal to the width of the light blocking members 430 disposed in two peripheral areas 20 located in adjacent display panels. In such an embodiment, the light blocking member 430 disposed in the peripheral area 20 of the display panel may be even less recognized.

In an embodiment of the display device 100 according to the invention, the first and second widths a1 and a2 of the light blocking member 430 disposed in the display area 10 may be the same as the third and fourth widths a3 and a4 of the light blocking member 430 disposed in the two adjacent peripheral areas 20. Accordingly, when a user of the display device 100 views an image displayed on the display device 100, the user may not visually perceive a line at a boundary between adjacent display panels in the image.

In such an embodiment, when a large display panel is implemented by using the first, second, third, and fourth display panels 101, 102, 103, and 104, which are small display panels having relatively low prices, a manufacturing cost of the display device 100 may be relatively reduced.

In an alternative embodiment, an aperture ratio of the sub-pixel may be increased (e.g., a size of each of the first to third openings 431, 432, and 433 of the light blocking member 430 may be increased), so that visual recognition of the light blocking member 430 disposed in the peripheral area 20 may be reduced.

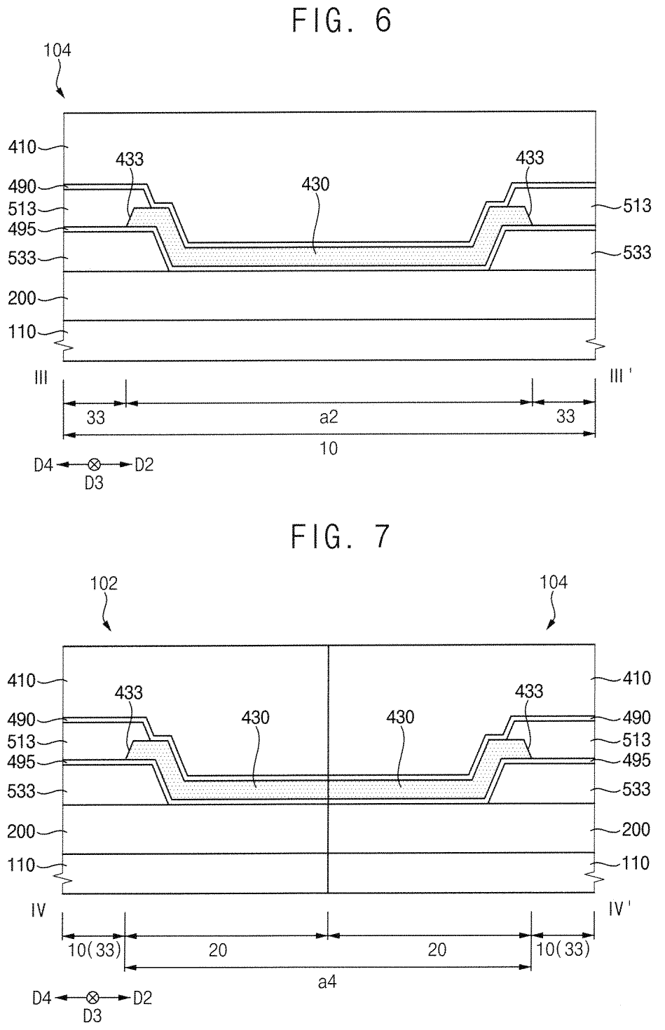

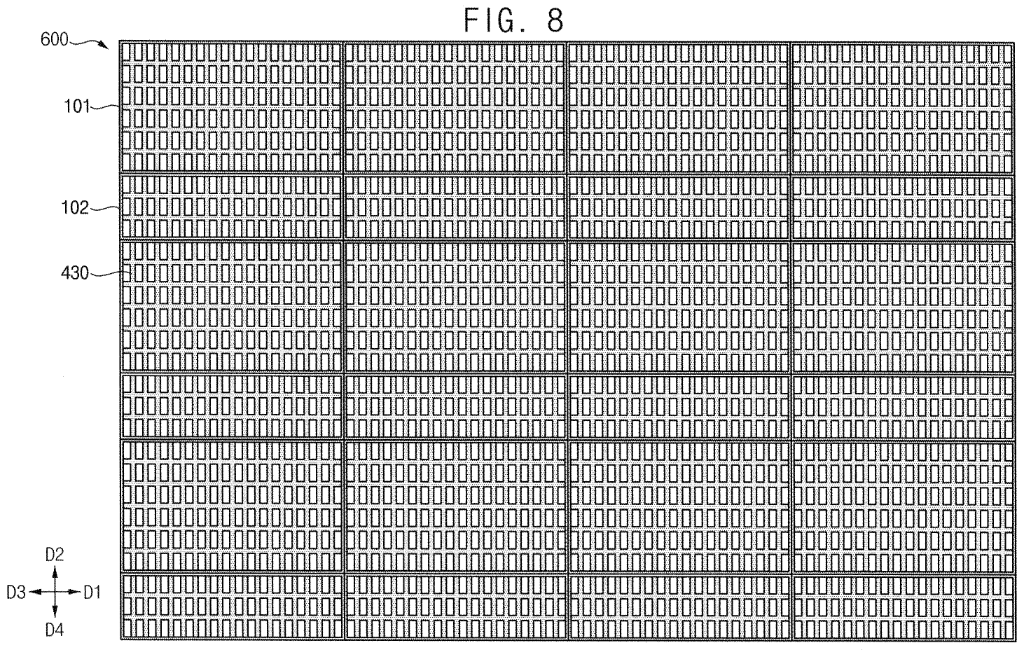

FIG. 4 is a cross-sectional view taken along line I-I′ of the display device of FIG. 2, and FIG. 5 is a cross-sectional view taken along line II-II′ of the display device of FIG. 2. FIG. 6 is a cross-sectional view taken along line III-III′ of the display device of FIG. 2, and FIG. 7 is a cross-sectional view taken along line IV-IV′ of the display device of FIG. 2.

Referring to FIGS. 3, 4, 5, 6, and 7, an embodiment of the display device 100 may include first, second, third, and fourth display panels 101, 102, 103, and 104. In such an embodiment, each of the first, second, third, and fourth display panels 101, 102, 103, and 104 may include a substrate 110, a sub-pixel structure 200, a light blocking member 430, optical filters 530, a first capping layer 495, color filters 510, a second capping layer 490, an overcoating layer 410, and the like. In such an embodiment, the optical filters 530 may include a first optical filter 531, a second optical filter 532, and a third optical filter 533, and the color filters 510 may include a first color filter 511, a second color filter 512, and a third color filter 513. In such an embodiment, first to third openings 431, 432, and 433 are defined through the light blocking member 430, and the sub-pixel structure 200 may include semiconductor elements, insulating layers, first and second signal wires, first to third sub-pixels, and the like.

The substrate 110 may include a transparent or opaque material. The substrate 110 may include at least one selected from a quartz substrate, a synthetic quartz substrate, a calcium fluoride substrate, a fluorine-doped quartz (“F-doped quartz”) substrate, a soda lime glass substrate, a non-alkali glass substrates, and the like.

In an alternative embodiment, the substrate 110 may be a transparent resin substrate having flexibility. In one embodiment, for example, the transparent resin substrate that may be used as the substrate 110 include a polyimide substrate. In such an embodiment, the polyimide substrate may have a stacked structure including a first polyimide layer, a barrier film layer, and a second polyimide layer.

In an embodiment, where the display device 100 includes the display area 10 including the first, second, and third sub-pixel areas 31, 32, and 33, and the peripheral area 20, the substrate 110 may also be divided into first, second, and third sub-pixel areas 31, 32 and 33, a display area 10, and a peripheral area 20.

The sub-pixel structure 200 may be disposed on the substrate 110. In one embodiment, for example, the semiconductor element, the insulating layers, the first signal wires, and the like may be disposed in the display area 10 on the substrate 110, and the second signal wires, the insulating layers, and the like may be disposed in the peripheral area 20 on the substrate 110. In an embodiment, the first to third sub-pixels may be disposed in the first, second, and third sub-pixel areas 31, 32, and 33, respectively, disposed on the semiconductor element, the insulating layers, and the first signal wires. An image may be displayed in the display area 10 through the first to third sub-pixels.

The first optical filter 531 may be disposed in the first sub-pixel area 31 and a part of the display area 10 adjacent to the first sub-pixel area 31 on the sub-pixel structure 200 (see the first optical filter 531 of the first display panel 101 shown in FIG. 4 and the first optical filter 531 of the second display panel 102 shown in FIG. 5). The first optical filter 531 may overlap the first color filter 511, and may be disposed under the first color filter 511. In such an embodiment, the first optical filter 531 may be disposed on the first sub-pixel. Light emitted from the first sub-pixel may pass through the first optical filter 531. The first optical filter 531 may convert blue light into red light. The first optical filter 531 may include a plurality of quantum dots configured to absorb blue light and emit red light.

The second optical filter 532 may be disposed in the second sub-pixel area 32 and a part of the display area 10 adjacent to the second sub-pixel area 32 on the sub-pixel structure 200 (e.g., see the second optical filter 532 of the first display panel 101 shown in FIG. 4). The second optical filter 532 may overlap the second color filter 512, and may be disposed under the second color filter 512. In such an embodiment, the second optical filter 532 may be disposed on the second sub-pixel. Light emitted from the second sub-pixel may pass through the second optical filter 532. The second optical filter 532 may convert blue light into green light. In one embodiment, for example, the second optical filter 532 may include a plurality of quantum dots configured to absorb blue light and emit green light.

The third optical filter 533 may be disposed in the third sub-pixel area 33 and a part of the display area 10 adjacent to the third sub-pixel area 33 on the sub-pixel structure 200 (e.g., see the third optical filter 533 of the first display panel 101 shown in FIG. 5, the third optical filter 533 of the fourth display panel 104 shown in FIG. 6, the third optical filter 533 of the second display panel 102 shown in FIG. 7, and the third optical filter 533 of the fourth display panel 104 shown in FIG. 7). The third optical filter 533 may overlap the third color filter 513, and may be disposed under the third color filter 513. In such an embodiment, the third optical filter 533 may be disposed on the third sub-pixel. Light emitted from the third sub-pixel may pass through the third optical filter 533. The third optical filter 533 may transmit blue light. In one embodiment, for example, the third optical filter 533 may include a scattering material that intactly emits blue light.

In one embodiment, for example, the quantum dots included in the first optical filter 531 and the second optical filter 532 may include at least one nanocrystal selected from a silicon (Si)-based nanocrystal, a group II-VI-based compound semiconductor nanocrystal, a group III-V-based compound semiconductor nanocrystal, a group IV-VI-based compound semiconductor nanocrystal, and a mixture thereof. The group II-VI-based compound semiconductor nanocrystal may be at least one selected from CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group III-V-based compound semiconductor nanocrystal may be at least one selected from GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs. The group IV-VI-based compound semiconductor nanocrystal may be SbTe.

In an embodiment, the quantum dots included in the first and second optical filters 531 and 532 may include a same material as each other, and an emission wavelength may vary according to a size of the quantum dot. In such an embodiment, as the size of the quantum dot decreases, light of a shorter wavelength may be emitted. Accordingly, light within a desired visible light region may be emitted by adjusting the size of the quantum dots included in the first and second optical filters 531 and 532.

In an embodiment, the quantum dots included in the first optical filter 531 and the second optical filter 532 may include or be formed of a same material as each other, and the size of the quantum dots included in the first optical filter 531 may be larger than the size of the quantum dots included in the second optical filter 532.

The third optical filter 533 may include TiO, ZrO, AlO₃, In₂O₃, ZnO, SnO₂, Sb₂O₃, ITO, and the like. However, a material of the third optical filter 533 is not limited thereto, and may be variously modified into any material that scatters blue light without converting the blue light.

Accordingly, the optical filters 530, through which the first optical filter 531, the second optical filter 532, and the third optical filter 533 are defined, may be disposed in each of the first, second, third, and fourth display panels 101, 102, 103, and 104.

The first capping layer 495 may be disposed in the display area 10 and the peripheral area 20 on the optical filters 530 and the sub-pixel structure 200. In one embodiment, for example, the first capping layer 495 may be disposed along a profile of the optical filters 530 with a uniform thickness to cover the optical filters 530 on the sub-pixel structure 200. In an embodiment, the first capping layer 495 may sufficiently cover the optical filters 530 on the sub-pixel structure 200, and may have a substantially flat top surface without creating a step around the optical filters 530. The first capping layer 495 may include an inorganic insulating material or an organic insulating material. In an embodiment, the first capping layer 495 may include an inorganic insulating material such as silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), and titanium oxide (TiOₓ). In an alternative embodiment, the first capping layer 495 may have a multilayer structure including a plurality of insulating layers. In one embodiment, for example, the insulating layers of the first capping layer 495 may have mutually different thicknesses, or may include mutually different materials.

In an embodiment, the light blocking member 430 may be disposed in the display area 10 and the peripheral area 20 except for the first, second, and third sub-pixel areas 31, 32, and 33 on the first capping layer 495. In such an embodiment, first to third openings 431, 432, and 433 are defined through the light blocking member 430, and the first to third openings 431, 432, and 433 may overlap the first, second, and third sub-pixel areas 31, 32, and 33, respectively. In such an embodiment, opposing side portions of the light blocking member 430 may be disposed between the optical filters 530 and the color filters 510 in the display area 10. In one embodiment, for example, the light blocking member 430 may block or absorb light incident from the outside. The light blocking member 430 may include an organic material such as a photoresist, a polyacryl-based resin, a polyimide-based resin, a polyamide-based resin, a siloxane-based resin, an acryl-based resin, and an epoxy-based resin. In an embodiment, the light blocking member 430 may be substantially opaque. In one embodiment, for example, the light blocking member 430 may further include a light blocking material to absorb light. The light blocking material may include at least one material selected from carbon black, titanium nitride oxide, titanium black, phenylene black, aniline black, cyanine black, nigrosine acid black, a black resin, and the like.

In an embodiment, as shown in FIG. 4, a width of the light blocking member 430 located between the first opening 431 and the second opening 432 that are adjacent to each other in the first direction D1 may be defined as the first width a1. In such an embodiment, as shown in FIG. 5, a width of the light blocking members 430 disposed in two adjacent peripheral areas 20 in the first and second display panels 101 and 102 that are adjacent to each other may be defined as the third width a3. In such an embodiment, as shown in FIG. 6, a width of the light blocking member 430 located between two third openings 433 that are adjacent to each other in the second direction D2 may be defined as the second width a2. In such an embodiment, as shown in FIG. 7, a width of the light blocking members 430 disposed in two adjacent peripheral areas 20 in the second and fourth display panels 102 and 104 that are adjacent to each other may be defined as the fourth width a4.

In an embodiment, the first width a1, the second width a2, the third width a3, and the fourth width a4 may all be equal to each other. In such an embodiment, each of the first to fourth widths a1, a2, a3, and a4 may be twice the width of the light blocking member 430 located in the peripheral area 20 of each of the first, second, third, and fourth display panels 101, 102, 103, and 104.

Referring to FIGS. 3 to 7, the first color filter 511 may be disposed in the first sub-pixel area 31 and a part of the display area 10 adjacent to the first sub-pixel area 31 on the first capping layer 495 and a part of the light blocking member 430 (see the first color filter 511 of the first display panel 101 shown in FIG. 4 and the first color filter 511 of the second display panel 102 shown in FIG. 5). In an embodiment, the first color filter 511 may overlap the first optical filter 531, and may be disposed on the first optical filter 531. In such an embodiment, the first color filter 511 may be disposed on the first sub-pixel. In an embodiment, the first color filter 511 may be disposed in the first opening 431. After the light emitted from the first sub-pixel passes through the first optical filter 531, the light may pass through the first color filter 511. The first color filter 511 may transmit red light, and may be a color filter having a red color.

The second color filter 512 may be disposed in the second sub-pixel area 32 and a part of the display area 10 adjacent to the second sub-pixel area 32 on the first capping layer 495 and a part of the light blocking member 430 (e.g., see the second color filter 512 of the first display panel 101 shown in FIG. 4). In an embodiment, the second color filter 512 may overlap the second optical filter 532, and may be disposed on the second optical filter 532. In such an embodiment, the second color filter 512 may be disposed on the second sub-pixel. In such an embodiment, the second color filter 512 may be disposed in the second opening 432. After the light emitted from the second sub-pixel passes through the second optical filter 532, the light may pass through the second color filter 512. The second color filter 512 may transmit green light, and may be a color filter having a green color.

The third color filter 513 may be disposed in the third sub-pixel area 33 and a part of the display area 10 adjacent to the third sub-pixel area 33 on the first capping layer 495 and a part of the light blocking member 430 (e.g., see the third color filter 513 of the first display panel 101 shown in FIG. 5, the third color filter 513 of the fourth display panel 104 shown in FIG. 6, the third color filter 513 of the second display panel 102 shown in FIG. 7, and the third color filter 513 of the fourth display panel 104 shown in FIG. 7). In an embodiment, the third color filter 513 may overlap the third optical filter 533, and may be disposed on the third optical filter 533. In such an embodiment, the third color filter 513 may be disposed on the third sub-pixel. In such an embodiment, the third color filter 513 may be disposed in the third opening 433. After the light emitted from the third sub-pixel passes through the third optical filter 533, the light may pass through the third color filter 513. The third color filter 513 may transmit blue light, and may be a color filter having a blue color.

Accordingly, the color filters 510 including the first color filter 511, the second color filter 512, and the third color filter 513 may be provided. The color filters 510 may be manufactured by using a photosensitive resin, a color photoresist, or the like.

The second capping layer 490 may be disposed in the display area 10 and the peripheral area 20 on the color filters 510, the light blocking member 430, and the first capping layer 495. In one embodiment, for example, the second capping layer 490 may be disposed along a profile of the color filters 510 and the light blocking member 430 with a uniform thickness to cover the color filters 510 and the light blocking member 430 on the first capping layer 495. In an alternative embodiment, the second capping layer 490 may sufficiently cover the color filters 510 and the light blocking member 430 on the first capping layer 495, and may have a substantially flat top surface without creating a step around the color filters 510 and the light blocking member 430. The second capping layer 490 may include an inorganic insulating material or an organic insulating material. In an embodiment, the second capping layer 490 may include an inorganic insulating material. In an alternative embodiment, the second capping layer 490 may have a multilayer structure including a plurality of insulating layers. In one embodiment, for example, the insulating layers of the second capping layer 490 may have mutually different thicknesses, or may include mutually different materials.

The overcoating layer 410 may be disposed in the display area 10 and the peripheral area 20 on the second capping layer 490. In an embodiment, the overcoating layer 410 may be disposed over the whole of the first, second, third, and fourth display panels 101, 102, 103, and 104. The overcoating layer 410 may have a relatively thick thickness, and may protect the color filters 510, the optical filters 530, the light blocking member 430, the sub-pixel structure 200, and the like. The overcoating layer 410 may include a high-hardness polymer material such as siloxane.

Accordingly, the display device 100 including the substrate 110, the sub-pixel structure 200, the light blocking member 430, the optical filters 530, the first capping layer 495, the color filters 510, the second capping layer 490, the overcoating layer 410, and the like may be provided.

In an embodiment, the display device 100 may be an organic light emitting diode display device, but not being limited thereto. Alternatively, the display device 100 may be a liquid crystal display device (“LCD”), a field emission display device (“FED”), a plasma display device (“PDP”), an electrophoretic display device (“EPD”), or an electronic display.

FIG. 8 is a plan view showing a display device according to an alternative embodiment of the invention. A display device 600 illustrated in FIG. 8 may have a configuration that is substantially the same as or similar to the configuration of the display device 100 described above with reference to FIGS. 1 to 7 except for a shape of the first display panel 101 and a shape of the second display panel 102. Accordingly, any repetitive detailed descriptions of the same or like components of the display device 600 in FIG. 8 as the components described above with reference to FIGS. 1 to 7 will hereinafter be omitted.

Referring to FIG. 8, an embodiment of the display device 600 may include first and second display panels 101 and 102. In such an embodiment, each of the first display panel 101 and the second display panel 102 may be a display panel having a relatively large size when compared with those of the display device 100 of FIG. 1. In one embodiment, for example, the first display panel 101 of FIG. 8 may have a size corresponding to an overall size of the four display panels shown in FIG. 1, and the second display panel 102 of FIG. 8 may have a size corresponding to an overall size of the two display panels shown in FIG. 1.

In such an embodiment, as shown in FIG. 8, in a plan view of the display device 600, the first display panels 101 may be arranged in the first direction D1. In such an embodiment, the second display panels 102 may be located in a fourth direction D4 that is opposite to the second direction D2 from the first display panels 101, and may be arranged in the first direction D1. In such an embodiment, as described above, the first and second display panels 101 and 102 may be repeatedly arranged to implement the display device 600 shown in FIG. 8.

In an embodiment, each of the first and second display panels 101 and 102 may have a display area 10 and a peripheral area 20. In such an embodiment, the peripheral area 20 may substantially surround the display area 10. The display area 10 may include first, second, and third sub-pixel areas 31, 32, and 33. The first, second, and third sub-pixel areas 31, 32, and 33 may be arranged in the first direction D1, and may be spaced apart from each other. In such an embodiment, the second sub-pixel area 32 may be spaced apart from the first sub-pixel area 31 in the first direction D1, and the third sub-pixel area 33 may be spaced apart from the second sub-pixel area 32 in the first direction D1. In one embodiment, for example, in a plan view of the display device 600, the first, second, and third sub-pixel areas 31, 32, and 33 may be repeatedly arranged in the first direction D1 and the second direction D2.

In an embodiment, each of the first and second display panels 101 and 102 may further include a light blocking member 430. In each of the first and second display panels 101 and 102, the light blocking member 430 may be disposed in the display area 10 and the peripheral area 20, and first, second, and third openings 431, 432, and 433 may be defined through the light blocking member 430 to overlap the first, second, and third sub-pixel areas 31, 32, and 33, respectively. In such an embodiment, the light blocking member 430 may be disposed in the display area 10 except for the first, second, and third sub-pixel areas 31, 32, and 33, and the peripheral area 20. In one embodiment, for example, the first opening 431 may overlap the first sub-pixel area 31, the second opening 432 may overlap the second sub-pixel area 32, and the third opening 433 may overlap the third sub-pixel area 33. The light generated from the sub-pixels may be emitted to the outside through the first to third openings 431, 432, and 433. The first to third openings 431, 432, and 433 may have a same size and a same shape as each other.

In an embodiment, as described above, a first width a1 and a second width a2 of the light blocking member 430 located between two adjacent openings among the first to third openings 431, 432, and 433 may be equal to each other. In one embodiment, for example, the first width a1 may correspond to a width of the light blocking member 430 located between two openings that are adjacent to each other in the first direction D1 among the first to third openings 431, 432, and 433, and the second width a2 may correspond to a width of the light blocking member 430 located between two openings that are adjacent to each other in the second direction D2 among the first to third openings 431, 432, and 433.

In such an embodiment, a third width a3 and a fourth width a4 of the light blocking members 430 disposed in two adjacent peripheral areas among the peripheral areas 20 in adjacent display panels among the first and second display panels 101 and 102 may be the same as the first width a1 and the second width a2. In such an embodiment, the third width a3 of the peripheral areas 20 of the first display panels 101 in the first direction D1, which are adjacent to a portion where the first display panels 101 make contact with each other, may be equal to the first width a1 of the light blocking member 430 located between the two openings that are adjacent to each other in the first direction D1 among the first to third openings 431, 432, and 433. In such an embodiment, the fourth width a4 of the peripheral area 20 of the first display panel 101 and the peripheral area 20 of the second display panel 102 in the second direction D2, which are adjacent to a portion where the first display panel 101 and the second display panel 102 make contact with each other, may be equal to the second width a2 of the light blocking member 430 located between the two openings that are adjacent to each other in the second direction D2 among the first to third openings 431, 432, and 433. In such an embodiment, the third width a3 of the peripheral areas 20 of the first display panels 101 in the first direction D1, which are adjacent to a portion where the first display panels 101 make contact with each other, may be equal to the fourth width a4 of the peripheral area 20 of the first display panel 101 and the peripheral area 20 of the second display panel 102 in the second direction D2, which are adjacent to a portion where the first display panel 101 and the second display panel 102 make contact with each other. Accordingly, the first width a1, the second width a2, the third width a3, and the fourth width a4 may all be equal to each other.

In an embodiment, each of the first to fourth widths a1, a2, a3, and a4 may be twice a width of the light blocking member 430 located in the peripheral area 20 of each of the first and second display panels 101 and 102.

Accordingly, the display device 100 including the first and second display panels 101 and 102 may be provided.

According to embodiments of the invention, the display device 600 may include first and second display panels 101 and 102 manufactured in mutually different sizes and mutually different shapes. In an embodiment where the display device 600 includes first and second display panels 101 and 102 having various sizes and various shapes, the first and second widths a1 and a2 of the light blocking member 430 disposed in the display area 10 may be the same as the third and fourth widths a3 and a4 of the light blocking member 430 disposed in the peripheral area 20. Accordingly, when a user of the display device 600 views an image displayed on the display device 600, the user may not visually perceive a line at a boundary between adjacent display panels in the image.

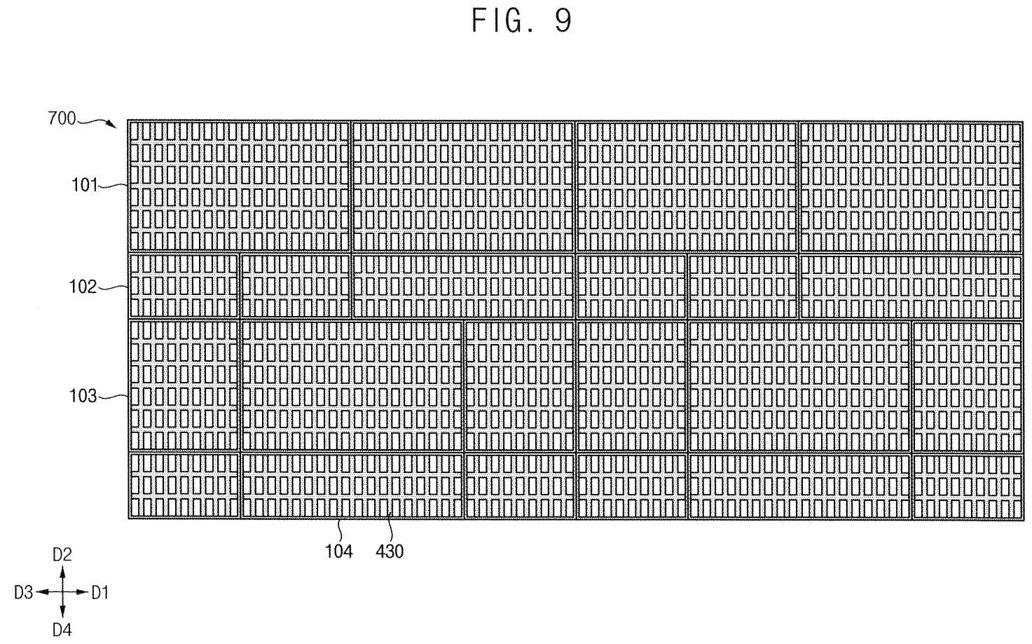

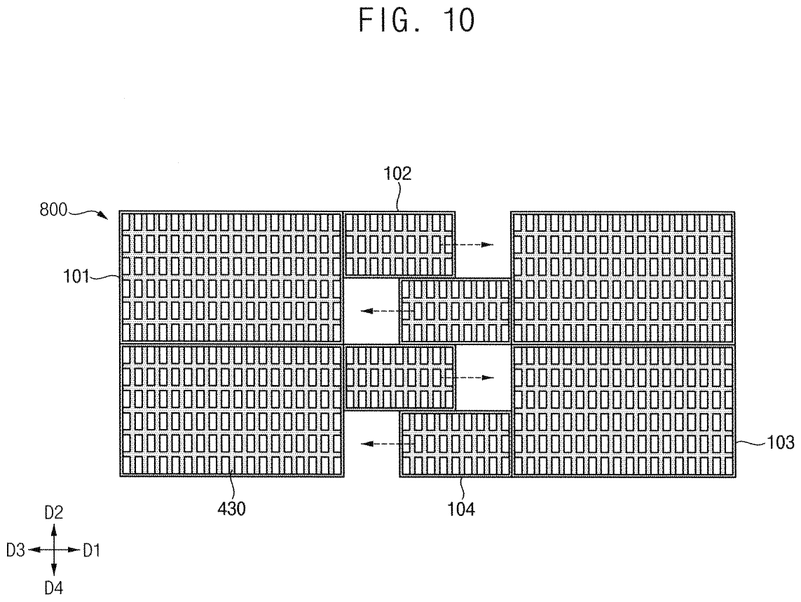

FIG. 9 is a plan view showing a display device according to embodiments of the invention. A display device 700 illustrated in FIG. 9 may have a configuration that is substantially the same as or similar to the configuration of the display device 100 described with reference to FIGS. 1 to 7 except for a shape of each of the first, second, and fourth display panels 101, 102, and 104. Accordingly, any repetitive detailed descriptions of the same or like components of the display device shown in FIG. 9 as the components described above with reference to FIGS. 1 to 7 will hereinafter be omitted.

Referring to FIG. 9, an embodiment of the display device 700 may include first, second, third, and fourth display panels 101, 102, 103, and 104. in such an embodiment, each of the first, third, and fourth display panels 101, 103, and 104 of FIG. 9 may be a display panel having a relatively large size when compared with the first, third, and fourth display panels 101, 103, and 104 shown in FIG. 1, and the second display panel 102 of FIG. 9 may be the same as the second display panel 102 of FIG. 1. In one embodiment, for example, the first display panel 101 of FIG. 9 may have a size corresponding to an overall size of the four display panels shown in FIG. 1, and each of the third and fourth display panels 103 and 104 of FIG. 9 may have a size corresponding to an overall size of the two display panels shown in FIG. 1. In one embodiment, for example, the third display panel 103 of FIG. 9 may have a shape formed by combining two display panels of FIG. 1 that are adjacent to each other in the second direction D2, and the fourth display panel 104 of FIG. 9 may have a shape formed by combining two display panels of FIG. 1 that are adjacent to each other in the first direction D1.

In an embodiment, as shown in FIG. 9, in a plan view of the display device 700, the first, second, third, and fourth display panels 101, 102, 103, and 104 may be combined with each other to implement the display device 700 shown in FIG. 9.

FIG. 10 is a plan view showing a display device according to embodiments of the invention. A display device 800 illustrated in FIG. 10 may have a configuration that is substantially the same as or similar to the configuration of the display device 100 described with reference to FIGS. 1 to 7 except for shapes of the first and third display panels 101 and 103. Accordingly, any repetitive detailed descriptions of the same or like components of the display device 800 shown in FIG. 10 as the components described above with reference to FIGS. 1 to 7 will hereinafter be omitted.

Referring to FIG. 10, an embodiment of the display device 800 may include first, second, third, and fourth display panels 101, 102, 103, and 104. In such an embodiment, each of the first and third display panels 101 and 103 of FIG. 10 may be a display panel having a relatively large size when compared with the first and third display panels 101 and 103 of FIG. 1, and each of the second and fourth display panels 102 and 104 of FIG. 10 may be the same as the second and fourth display panels 102 and 104 of FIG. 1. In one embodiment, for example, each of the first and third display panels 101 and 103 of FIG. 10 may have a size corresponding to an overall size of the four display panels of FIG. 1.

In an embodiment, as shown in FIG. 10, in a plan view of the display device 800, the second display panel 102 may be bonded to one side of the first display panel 101, and the fourth display panel 104 may be bonded to one side of the third display panel 103. In one embodiment, for example, the first and second display panels 101 and 102 and the third and fourth display panels 103 and 104 may have a sawtooth shape. In such an embodiment, the first and second display panels 101 and 102 may move in the first direction D1, and the third and fourth display panels 103 and 104 may move in a third direction D3 that is opposite to the first direction D1, so that the first and second display panels 101 and 102 may be coupled to the third and fourth display panels 103 and 104. Accordingly, in an embodiment of a method of manufacturing the display device 800, the first, second, third, and fourth display panels 101, 102, 103, and 104 may be relatively easily coupled to each other.

Embodiments of the invention described herein may be applied to various electronic devices including a display device. Embodiments of the invention may be applied to numerous electronic devices such as a vehicle-display device, a ship-display device, an aircraft-display device, portable communication devices, display devices for display or for information transfer, and a medical-display device, for example.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a plurality of display panels,
wherein each of the display panels include:
a substrate including a display area and a peripheral area, wherein the display area includes sub-pixel areas; and
a light blocking member disposed in the display area and the peripheral area on the substrate, wherein a plurality of openings is defined through the light blocking member to overlap the sub-pixel areas, and
wherein a first width of the light blocking member located between two adjacent openings among the openings is twice a width of the light blocking member located in the peripheral area.

2. The display device of claim 1, wherein the openings have a same size and a same shape as each other.

3. The display device of claim 1, wherein, in a plan view of the display device, the display panels are repeatedly arranged in a first direction and a second direction orthogonal to the first direction.

4. The display device of claim 3, wherein the display panels are arranged in a lattice shape.

5. The display device of claim 3, wherein a second width of the light blocking members disposed in two adjacent peripheral areas among the peripheral areas in adjacent display panels among the display panels is equal to the first width.

6. The display device of claim 1, wherein a width of the light blocking member located between two openings which are adjacent to each other in a first direction among the openings is equal to a width of the light blocking member located between two openings which are adjacent to each other in a second direction orthogonal to the first direction among the openings.

7. The display device of claim 1, wherein the display panels have a same size and a same shape as each other.

8. The display device of claim 1, wherein the display panels include:
a first display panel; and
a second display panel making contact with a first side of the first display panel, and
wherein the first display panel and the second display panel are arranged in a first direction.

9. The display device of claim 8, wherein a total width of a peripheral area of the first display panel and a peripheral area of the second display panel in the first direction, which are adjacent to a boundary where the first display panel and the second display panel make contact with each other, is equal to a width of the light blocking member located between two openings which are adjacent to each other in the first direction among the openings.

10. The display device of claim 9, wherein
the display panels further include a third display panel making contact with a second side of the first display panel, and
the first display panel and the third display panel are arranged in a second direction orthogonal to the first direction.

11. The display device of claim 10, wherein a total width of a peripheral area of the first display panel and a peripheral area of the third display panel in the second direction, which are adjacent to a boundary where the first display panel and the third display panel make contact with each other, is equal to a width of the light blocking member located between two openings which are adjacent to each other in the second direction among the openings.

12. The display device of claim 11, wherein the total width of the peripheral area of the first display panel and the peripheral area of the second display panel in the first direction, which are adjacent to the boundary where the first display panel and the second display panel make contact with each other, is equal to the total width of the peripheral area of the first display panel and the peripheral area of the third display panel in the second direction, which are adjacent to the boundary where the first display panel and the third display panel make contact with each other.

13. The display device of claim 1, wherein
the sub-pixel areas include first, second, and third sub-pixel areas, and
each of the display panels further includes first, second, and third sub-pixel structures disposed in the first to third sub-pixel areas on the substrate, respectively.

14. The display device of claim 13, wherein each of the display panels further includes:
first, second, and third optical filters disposed on the first to third sub-pixel structures, respectively; and
first, second, and third color filters disposed on the first to third optical filters, respectively.

15. The display device of claim 14, wherein the first to third color filters are disposed in the openings, respectively.

16. The display device of claim 14, wherein opposing side portions of the light blocking member in the display area are disposed between the first optical filter and the first color filter, between the second optical filter and the second color filter, and between the third optical filter and the third color filter.

17. The display device of claim 1, wherein sub-pixel areas located at an outermost periphery of among the sub-pixel areas in one of the display panels are aligned with a boundary between the display area and the peripheral area.

18. The display device of claim 1, wherein, in a plan view of the display device, the sub-pixel areas are repeatedly arranged in a first direction and a second direction orthogonal to the first direction.

19. The display device of claim 1, wherein
the peripheral area surrounds the display area, and
the light blocking member is disposed in the peripheral area and the display area except for the sub-pixel areas.
